(19) United States
(12) Patent Application Publication
(10) Pub. No.: US 2024/0238935 A1
(43) Pub. Date: Jul. 18, 2024

(54) CHEMICAL MECHANICAL POLISHING APPARATUS

(71) Applicant: SAMSUNG ELECTRONICS CO., LTD., SUWON-SI (KR)

(72) Inventors: Gihwan Kim, Suwon-si (KR); Donghoon Kwon, Suwon-si (KR); Kihoon Jang, Suwon-si (KR)

(21) Appl. No.: 18/396,918

(22) Filed: Dec. 27, 2023

(30) Foreign Application Priority Data
Jan. 12, 2023 (KR) 10-2023-0004724

(51) Int. Cl. B24B 37/015

(52) U.S. Cl. CPC B24B 37/015

(57) ABSTRACT

A chemical mechanical polishing apparatus, may include: a turntable; a CMP pad installed on an upper surface of the turntable; a polishing head disposed above the turntable and contacting a wafer with the CMP pad to press the wafer; a slurry supply unit supplying slurry to the CMP pad; and a temperature control unit disposed between the slurry supply unit and the polishing head, wherein the temperature control unit may be provided with a body disposed above the CMP pad; and heating members disposed on a bottom surface of the body to heat the CMP pad, wherein the body may be provided with a suction port disposed between the heating members to suction steam.

### CROSS-REFERENCE TO RELATED APPLICATION(S)

This application claims priority under 35 U.S.C. § 119 to Korean Patent Application No. 10-2023-0004724 filed on Jan. 12, 2023 in the Korean Intellectual Property Office, the disclosure of which is incorporated herein by reference in its entirety.

### BACKGROUND

### 1. FIELD

The present inventive concept relates to a chemical mechanical polishing apparatus.

### 2. DESCRIPTION OF RELATED ART

In manufacturing a semiconductor device, a chemical mechanical polishing (CMP) process using a chemical mechanical polishing (CMP) apparatus is used to planarize a wafer. The chemical mechanical polishing (CMP) process is a process of polishing a surface of a wafer using a chemical mechanical interaction between the wafer and a CMP pad.

Various modules for controlling a temperature of a polishing pad and a slurry in the chemical mechanical polishing process have been developed, and among the various modules, a non-contact steam injection module, which is effective in increasing the temperature of the polishing pad has been developed.

However, since the steam injection module injects steam, there is a concern for dilution of the slurry, and furthermore, since the steam could be disposed before a supply point of the slurry, the heated pad comes into contact with a disc after contacting the slurry, so that heat is lost and there is a problem in that efficiency is reduced.

### SUMMARY

An aspect of the present inventive concept is to provide a chemical mechanical polishing apparatus capable of preventing generation of particles due to condensation of water vapor.

According to an aspect of the present inventive concept, a chemical mechanical polishing apparatus may be provided, the chemical mechanical polishing apparatus including: a turntable; a CMP pad installed on an upper surface of the turntable; a polishing head disposed above the turntable and contacting a wafer with the CMP pad to press the wafer; a slurry supply unit supplying slurry to the CMP pad; and a temperature control unit disposed between the slurry supply unit and the polishing head, wherein the temperature control unit may be provided with a body disposed above the CMP pad; and heating members disposed on a bottom surface of the body to heat the CMP pad, wherein the body may be provided with a suction port disposed between the heating members to suction steam.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram illustrating a chemical mechanical polishing apparatus according to an example embodiment;

FIG. 2 is a bottom view illustrating a temperature control unit of a chemical mechanical polishing apparatus according to an example embodiment;

FIG. 3 is a side view illustrating a temperature control unit of a chemical mechanical polishing apparatus according to an example embodiment;

FIG. 4 is a bottom view illustrating a temperature control unit of the chemical mechanical polishing apparatus according to an example embodiment;

FIG. 5 is a bottom view illustrating a temperature control unit of a chemical mechanical polishing apparatus according to an example embodiment; and

FIG. 6 is a bottom view illustrating a temperature control unit of a chemical mechanical polishing apparatus according to an example embodiment.

### DETAILED DESCRIPTION

Hereinafter, embodiments of the present inventive concept will be described with reference to the accompanying drawings.

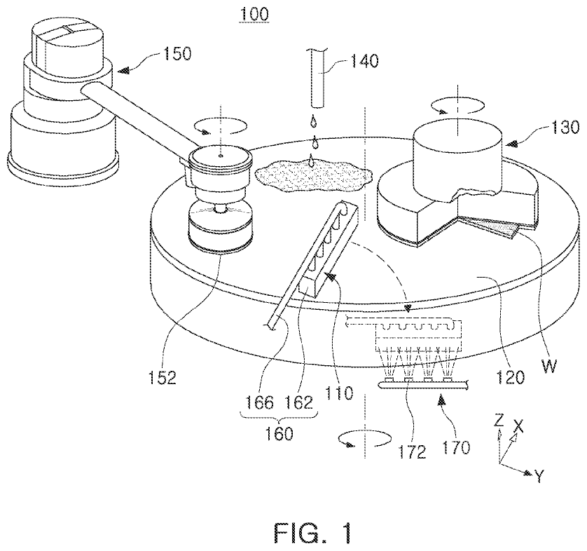

FIG. 1 is a schematic diagram illustrating a chemical mechanical polishing apparatus according to an example embodiment.

Referring to FIG. 1, a chemical mechanical polishing apparatus 100 according to an example embodiment may include a turntable 110, a CMP pad 120, a polishing head 130, a slurry supply unit 140, a conditioning unit 150, and a temperature control unit 160.

The turntable 110 may be rotatably installed on a rotating shaft, and an upper end portion of the turntable 110 has a circular plate shape. The turntable 110 may be rotated in a predetermined direction, for example, counterclockwise. In addition, a CMP pad 120 may be installed on an upper surface of the turntable 110.

The CMP pad 120 may be, for example, a hard polyurethane pad. Meanwhile, a polishing layer for polishing a wafer W may be provided on an upper surface of the CMP pad 120, and grooves may be provided on the polishing layer to improve polishing efficiency of the wafer W.

The polishing head 130 is disposed above the turntable 110 and contacts the wafer W with the CMP pad 120, where the polishing head 130 can be configured to apply a force normal to the turntable 110 to the wafer W. In addition, the polishing head 130 may be rotated in a predetermined direction, for example, counterclockwise. Accordingly, the wafer W mounted on a bottom surface of the polishing head 130 may contact the CMP pad 120 with a predetermined force (pressure), while being rotated. The polishing head can be configured to press the wafer against the CMP pad with a predetermined force.

The slurry supply unit 140 can supply a slurry to the CMP pad 120. As an example, the slurry supply unit 140 may be disposed between the polishing head 130 and the conditioning unit 150 in a rotational direction of the turntable 110. For example, the polishing head 130, the slurry supply unit 140, and the conditioning unit 150 may be sequentially disposed in the rotational direction of the turntable 110. Accordingly, the slurry supplied from the slurry supply unit 140 may be more smoothly provided to the polishing head 130. Meanwhile, when a CMP process is performed, chemical mechanical polishing of the wafer W may be performed using the slurry supplied from the slurry supply unit 140.

The conditioning unit 150 can be disposed at a rear end of the slurry supply unit 140, that is, between the slurry supply unit 140 and the temperature control unit 150 in the rotational direction of the turntable 110. As an example, the conditioning unit 150 may be an apparatus for conditioning a surface condition of the CMP pad 120, where the conditioning unit 150 may maintain surface roughness of the CMP pad 120 to be in an optimal state. In addition, the conditioning unit 150 may be provided with a disk 152 contacting the CMP pad 120.

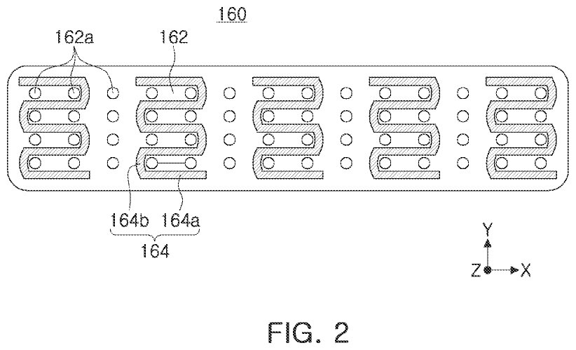

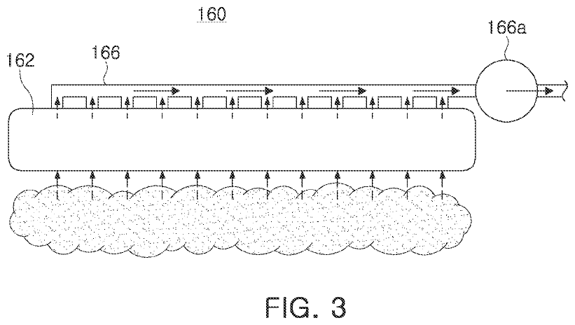

The temperature control unit 160 is disposed between the conditioning unit 150 and the polishing head 130. As an example, the temperature control unit 160 may include a body 162 and a heating member 164 as illustrated in more detail in FIGS. 2 and 3.

The body 162 is disposed above the CMP pad 120. As an example, the body 162 can have a rectangular parallelepiped shape, which may be disposed parallel to a direction from a central portion to an edge of the CMP pad 120. Meanwhile, the body 162 may be provided with a suction port 162a disposed between the heating member 164 to suction steam. The suction port 162a may be disposed between the heating members 164, so as not to interfere with the heating members 164. As an example, the plurality of suction ports 162a may be disposed to form a plurality of columns and rows. The suction ports 162a arranged in a plurality of columns and rows can form a 2-dimensional grid array, although other 2-dimensional arrays (e.g., hexagonal) are also contemplated.

Here, defining a term for a direction, a longitudinal direction means an X-axis direction of FIG. 1, a direction parallel to a long side of the body 162, and a width direction means a Y-axis direction of FIG. 1, a direction parallel to a short side of the body 162.

The suction port 162a suctions in water vapor generated when heated by the heating member 164 to prevent particle generation due to condensation of water vapor.

Meanwhile, a flow pipe 166 may be connected to and in fluid communication with the suction port 162a, so that the suctioned water vapor flows away from the body 162, and the suctioned water vapor may flow through the flow pipe 166, as shown, for example, in FIG. 3. A pump 166a may be provided in the flow pipe 166 to provide a suction force, so that water vapor may be introduced through the suction port 162a. The water vapor suctioned through the inlet of the suction port 162a can be reused. The flow pipe 166 can be connected to and in fluid communication with one or more suction ports 162a, and through which steam flows, where a pump can be connected to and in fluid communication with the flow pipe. The pump can be configured to provide a suction force to suction steam.

Meanwhile, the body 162 may be rotated to be positioned beyond the outer edge of the CMP pad 120. To this end, the body 162 may be connected to a driving unit, and when the body 162 is rotated to be disposed outside the CMP pad 120, the body 162 may be cleaned by a cleaning module 170. As described above, because cleaning is performed by the cleaning module 170, it is possible to prevent the slurry and water vapor from adhering. In other words, the body 162 is rotated to be disposed outside the CMP pad 120, and cleaning is performed by the cleaning module 170, thereby preventing slurry and water vapor from adhering to the body 162 and the heating member 164.

The heating member 164 is disposed on a bottom surface of the body 162, which can be proximal to the CMP pad 120, and configured to heat the CMP pad 120. As an example, a plurality of heating members 164 may be spaced apart from each other. For example, each of the five heating members 164 may be disposed in regions spaced apart from each other, where one row of inlets 162a may be located between the heating members 164. As an example, the heating member 164 may include a straight portion 164a disposed in a longitudinal direction and a connection portion 164b connecting the straight portions 164a to each other. The straight portion 164a can be parallel to a long axis of the body 162, whereas the connection portion 164b can be parallel to the short axis of the body 162. The straight portions can have a straight shape, and the connecting portions can have a curved shape. The connection portion 164b may be alternately disposed in one end portion and the other end portion of the straight portion 164a. The connection portion 164b can electrically connect adjacent pairs of the straight portions 164a, where the connection portion 164b can be on alternating ends of the straight portions 164a. The adjacent straight portions 164a and alternating connection portions 164b can form a serpentine layout. As an example, the heating member 164 may be any one of an IR lamp, a heater, and an IR laser. As described above, the heating member 164 can simultaneously heat the slurry and the CMP pad 120 before the slurry supplied from the slurry supply unit 140 is introduced to the polishing head 130, thereby improving thermal efficiency.

In various embodiments, the plurality of heating members 164 may be turned on/off separately for each region, and a temperature, heated by the plurality of heating members 164 may be different for each region. For example, since a temperature of a region in contact with the wafer by the polishing head 130 and a temperature of a region in contact with the conditioning unit 150 may be higher than a temperature in other regions, in this case, the heating member 164 may be controlled to lower a heating temperature by the heating member 164 in a region in contact with the wafer and a region in contact with the conditioning unit 150. A temperature of a first region, heated by at least a first subset of a plurality of heating members can be different from a temperature of a second region, heated by a remaining subset of the heating members. In addition, depending on a type of slurry supplied through the slurry supply unit 140, a temperature of the slurry may increase or decrease when heated by the heating member 164. Therefore, switching on/off of the heating member 164 may be controlled according to the type of slurry supplied. As such, the heating temperature of the heating member 164 can be controlled to achieve planarization of the CMP pad 120, and accordingly, a degree of planarization of the central portion and the edge of the wafer can be adjusted.

The cleaning module 170 serves to clean a bottom surface of the body 162 when the temperature control unit 160 is rotated and disposed outside the CMP pad 120, where the bottom surface of the body 162 can be proximal to the CMP pad 120. To this end, the cleaning module 170 may be provided with a spraying nozzle 172 for spraying distilled water, and clean the body 162 and the heating member 164 through distilled water, sprayed through the spray nozzle 172. Accordingly, it is possible to prevent the slurry and water vapor from adhering to the temperature control unit 160.

As described above, thermal efficiency may be improved by simultaneously heating the slurry and the CMP pad 120 before the slurry is introduced into the polishing head 130 through the heating member 164. In addition, since water vapor is suctioned through the suction port 162a, generation of particles due to condensation of water vapor can be prevented.

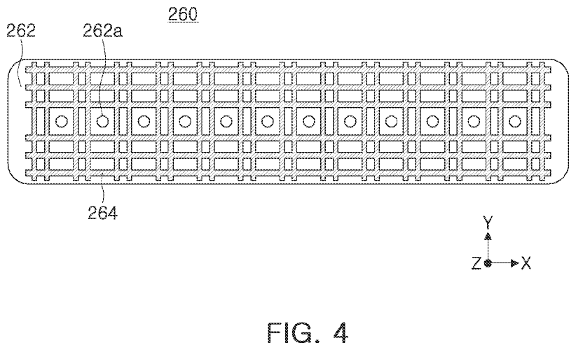

FIG. 4 is a bottom view illustrating a temperature control unit of a chemical mechanical polishing apparatus according to an example embodiment.

Referring to FIG. 4, a temperature control unit 260 may include a body 262 and a heating member 264.

The body 262 can be disposed above a CMP pad 120 (see FIG. 1). As an example, the body 262 can have a rectangular parallelepiped shape, where the long axis of the body 262 may be disposed parallel to a radial direction from a central portion to an edge of the CMP pad 120. Meanwhile, the body 262 may be provided with a suction port 262a disposed between heating members 264 to suction steam. As an example, the suction port 262a may be disposed on one or two straight lines in a longitudinal direction of the body 262. The suction ports 262a can form a linear pattern, where the suction ports 262a can be located within a grid pattern formed by the heating members 264. For example, the heating member 264 may be arranged to have a lattice shape, where a plurality of straight portions parallel with a long axis of the body 262 intersect with a plurality of straight portions parallel with a short axis of the body 262. In various embodiments, the heating member 264 may be any one of an IR lamp, a heater, and an IR laser. The suction ports can be disposed between intersecting straight portions of the heating member having the lattice shape.

Meanwhile, the plurality of heating members 264 may be separately turned on/off for each region, and a temperature heated by the plurality of heating members 264 may be different for each region. As described above, by controlling a heating temperature by the heating member 264, a degree of planarization of a central portion and an edge of a wafer may be adjusted.

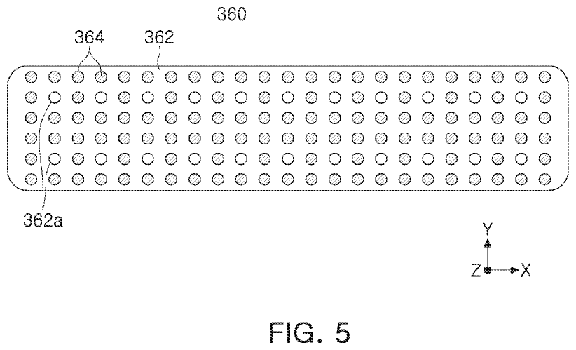

FIG. 5 is a bottom view illustrating a temperature control unit of a chemical mechanical polishing apparatus according to an example embodiment.

Referring to FIG. 5, a temperature control unit 360 may include a body 362 and a heating member 364.

The body 362 can be disposed above a CMP pad 120 (see FIG. 1). As an example, the body 362 can have a rectangular parallelepiped shape, and may be disposed parallel to a radial direction from a central portion to an edge of the CMP pad 120.

Meanwhile, the body 362 may be provided with a suction port 362a disposed between heating members 364 to suction steam. As an example, the suction port 362a may be disposed along two straight lines in a longitudinal direction of the body 362, where the suction ports 362a can be spaced apart and interspersed with heating members 364. The heating members 364 can be located between the suction ports 362a, where the suction ports 362a and heating members 364 can form a square or rectangular grid array.

In various embodiments, the heating member 364 can have a shape corresponding to the suction port 362a and may be disposed in a plurality of columns and rows together with the plurality of suction port 362a, where for example, the suction ports 362a can have a circular hole shape and heating members 364 can each have a circular cross-section. The heating member 364 may be any one of an IR lamp, a heater, and an IR laser.

In various embodiments, the plurality of heating members 364 may be turned on/off separately for each region, and a temperature heated by the plurality of heating members 364 may be different for each region. As described above, by controlling a heating temperature by the heating member 364, a degree of planarization of a central portion and an edge of a wafer may be adjusted.

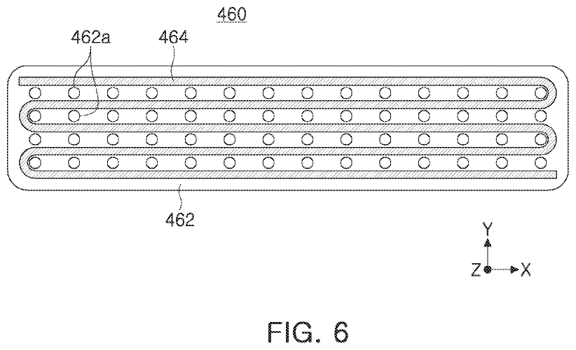

FIG. 6 is a bottom view illustrating a temperature control unit of a chemical mechanical polishing apparatus according to an example embodiment.

Referring to FIG. 6, a temperature control unit 460 may include a body 462 and a heating member 464.

The body 462 can be disposed above a CMP pad 120 (see FIG. 1). As an example, the body 462 can have a rectangular parallelepiped shape, and may be disposed parallel to a radial direction from a central portion of the CMP pad 120 to an edge of the CMP pad 120.

In various embodiments, the body 462 may be provided with a suction port 462a disposed between heating members 464 to suction steam. As an example, a plurality of suction ports 462a may be disposed along four straight lines in a longitudinal direction parallel to a long axis of the body 462. The heating member 464 may be composed of a single heater, and may have a curved (serpentine) shape, so as not to interfere with the suction port 462a. The plurality of suction ports 462a can be interspersed between adjacent portions of a single, unitary heating member 464, where the suction ports 462 can form a 2-dimensional grid array.

As set forth above, according to the present inventive concept, a chemical mechanical polishing device capable of preventing generation of particles due to condensation of water vapor may be provided.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present inventive concept as defined by the appended claims.

What is claimed is:

1. A chemical mechanical polishing apparatus, comprising:
a turntable;
a CMP pad installed on an upper surface of the turntable;
a polishing head disposed above the turntable and contacting a wafer with the CMP pad, wherein the polishing head is configured to press the wafer against the CMP pad;
a slurry supply unit configured to supply a slurry to the CMP pad; and
a temperature control unit disposed between the slurry supply unit and the polishing head,
wherein the temperature control unit includes
a body configured to be positioned above the CMP pad; and
one or more heating members disposed on a bottom surface of the body configured to heat the CMP pad,
wherein the body includes a suction port interspersed with the one or more heating members to suction steam.

2. The chemical mechanical polishing apparatus of claim 1, wherein the suction port is a plurality of suction ports arranged in a 2-dimensional array,
wherein the one or more heating members includes a plurality of heating members spaced apart from each other.

3. The chemical mechanical polishing apparatus of claim 2, wherein the plurality of heating members include two or more straight portions and a connection portion connecting two adjacent straight portions.

4. The chemical mechanical polishing apparatus of claim 1, wherein the one or more heating members have a lattice shape, and the suction port is a plurality of suction ports disposed between intersecting straight portions of the one or more heating members having the lattice shape.

5. The chemical mechanical polishing apparatus of claim 4, wherein the plurality of suction ports are disposed in a central portion of a bottom surface of the body in a longitudinal direction.

6. The chemical mechanical polishing apparatus of claim 1, wherein the suction port is a plurality of suction ports, wherein the plurality of suction ports are disposed along two straight lines disposed in the longitudinal direction of the body to form two rows, and each of the plurality of suction ports has a circular hole shape.

7. The chemical mechanical polishing apparatus of claim 6, wherein the one or more heating members are composed of an IR laser having a circular shape, and
the one or more heating members form a plurality of columns and rows together with the suction port.

8. The chemical mechanical polishing apparatus of claim 1, wherein the one or more heating members are composed of a single heater,
wherein the suction port is a plurality of suction ports, wherein the plurality of suction ports are spaced apart from each other and are adjacent to a straight portion of the heating member.

9. The chemical mechanical polishing apparatus of claim 1, wherein each of the one or more heating members is an IR lamp.

10. The chemical mechanical polishing apparatus of claim 1, further comprising:
a conditioning unit located between the slurry supply unit and the temperature control unit.

11. The chemical mechanical polishing apparatus of claim 10, wherein the conditioning unit includes a disk in contact with the CMP pad.

12. The chemical mechanical polishing apparatus of claim 1, wherein the body is connected to a flow pipe, wherein the flow pipe is connected to and in fluid communication with the suction port and through which steam flows.

13. The chemical mechanical polishing apparatus of claim 12, wherein a pump is connected to and in fluid communication with the flow pipe, wherein the pump is configured to provide a suction force to suction steam.

14. The chemical mechanical polishing apparatus of claim 2, wherein a temperature of a first region, heated by a first subset of the plurality of heating members is different from a temperature of a second region, heated by a remaining subset of the plurality of heating members.

15. The chemical mechanical polishing apparatus of claim 1, further comprising:
a cleaning module configures to clean the temperature control unit when the temperature control unit is rotated and disposed outside the CMP pad.

16. A chemical mechanical polishing apparatus, comprising:
a turntable;
a CMP pad installed on an upper surface of the turntable;
a polishing head disposed above the turntable and contacting a wafer with the CMP pad, wherein the polishing head is configured to press the wafer against the CMP pad;
a slurry supply unit configured to supply a slurry to the CMP pad;
a temperature control unit disposed between the slurry supply unit and the polishing head,
wherein the temperature control unit includes
a body configured to be positioned above the CMP pad; and
a plurality of heating members disposed on a bottom surface of the body configured to heat the CMP pad,
wherein a temperature of a first region, heated by at least a portion of the plurality of heating members is different from a temperature of a second region, heated by the remaining heating members.

17. The chemical mechanical polishing apparatus of claim 16, further comprising:
a conditioning unit located between the slurry supply unit and the temperature control unit.

18. The chemical mechanical polishing apparatus of claim 17, further comprising:
a cleaning module configures to clean the temperature control unit when the temperature control unit is rotated and disposed outside the CMP pad.

19. A chemical mechanical polishing apparatus, comprising:
a turntable;
a polishing head above the turntable;
a slurry supply unit configured to supply a slurry; and
a temperature control unit including a body having a plurality of suction ports and one or more heating members on a surface of the body proximal to the turntable, wherein the temperature control unit is between the slurry supply unit and the polishing head.

20. The chemical mechanical polishing apparatus of claim 19, further comprising:
a flow pipe connected to and in fluid communication with the plurality of suction ports, and
a pump connected to and in fluid communication with the flow pipe, wherein the pump is configured to provide a suction force.
